(19) United States
(12) Patent Application Publication
(10) Pub. No.: US 2023/0207487 A1
(43) Pub. Date: Jun. 29, 2023

(54) SEMICONDUCTOR PACKAGE INCLUDING STIFFENER

(71) Applicant: Samsung Electronics Co., Ltd., Suwon-si (KR)

(72) Inventors: Jinhyun KANG, Cheongju-si (KR); Haejung YU, Hwaseong-si (KR); Soohyun NAM, Hwaseong-si (KR); Ilbok LEE, Incheon (KR)

(73) Assignee: Samsung Electronics Co., Ltd., Suwon-si (KR)

(21) Appl. No.: 17/876,099

(22) Filed: Jul. 28, 2022

(30) Foreign Application Priority Data
Dec. 28, 2021 (KR) 10-2021-0189606

(51) Int. Cl. H01L 23/00

(52) U.S. Cl. CPC H01L 23/562; H01L 24/16; H01L 24/32; H01L 24/73; H01L 2224/16225; H01L 2224/32225; H01L 2224/73204

(57) ABSTRACT

A semiconductor package including a substrate including, at an upper surface thereof, an inner area and an edge area surrounding the inner area, a chip set on the inner area of the substrate, a stiffener set on the edge area of the substrate, the stiffener set including a plurality of stiffeners spaced apart from one another, and an adhesive member attaching the plurality of stiffeners to the substrate may be provided.

### CROSS-REFERENCE TO THE RELATED APPLICATION

This application claims priority to Korean Patent Application No. 10-2021-0189606, filed on Dec. 28, 2021, in the Korean Intellectual Property Office, the disclosure of which is incorporated herein by reference in its entirety.

### BACKGROUND

### 1. Field

Example embodiments of the disclosure relate to semiconductor packages.

### 2. Description of the Related Art

For next-generation high-performance communication appliances, a semiconductor package including a logic device and memory devices having a high bandwidth (HBM) are being highlighted. Such a semiconductor package may include an interposer mounted on a substrate, and a logic chip and a plurality of memory stacks mounted on the interposer.

In particular, for example, semiconductor packages designed to be suitable for mobile communication are manufactured to be thin and, as such, may be very weak against external physical stress such as warpage or the like.

### SUMMARY

Some example embodiments of the disclosure provide semiconductor packages that is capable of mitigating issues (e.g., warpage) caused by external physical stress.

A semiconductor package according to an example embodiment of the disclosure may include a substrate including, at an upper surface thereof, an inner area and an edge area surrounding the inner area, a chip set on the inner area of the substrate, a stiffener set on the edge area of the substrate, the stiffener set including a plurality of stiffeners spaced apart from one another, and an adhesive member attaching the plurality of stiffeners to the substrate.

A semiconductor package according to an example embodiment of the disclosure may include a substrate including, at an upper surface thereof, an inner area and an edge area surrounding the inner area, a chip set on the inner area of the substrate, a stiffener set on the edge area of the substrate, the stiffener set including a plurality of stiffeners having different coefficients of thermal expansion (CTEs), respectively, and an adhesive member attaching the plurality of stiffeners to the substrate.

A semiconductor package according to an example embodiment of the disclosure may include a substrate including, at an upper surface thereof, an inner area and an edge area surrounding the inner area, a chip set on the inner area of the substrate, the chip set including an interposer on the substrate and a logic chip and a memory stack on the interposer, a stiffener set on the edge area of the substrate, the stiffener set including a plurality of stiffeners spaced apart from one another and having different coefficients of thermal expansion (CTEs), respectively, and an adhesive member attaching the plurality of stiffeners to the substrate. A coefficients of thermal expansion (CTE) of each of the stiffeners, a CTE of the chip set, and a CTE of the substrate may be different.

### BRIEF DESCRIPTION OF THE DRAWINGS

FIG. 1 is a projected top view schematically showing a semiconductor package according to an example embodiment of the disclosure.

FIG. 2 is a schematic cross-sectional view taken along line I-I′ in FIG. 1.

FIG. 3 is a cross-sectional view showing a stiffener set 120 according to an example embodiment of the disclosure.

FIG. 4 shows detailed cross-sectional structures of a first stiffener according to some example embodiments of the disclosure.

FIG. 5 is a cross-sectional view showing a portion of a semiconductor package according to an example embodiment of the disclosure.

FIG. 6 is a cross-sectional view showing a portion of a semiconductor package according to an example embodiment of the disclosure.

FIG. 7 is a cross-sectional view showing a portion of a semiconductor package according to an example embodiment of the disclosure.

FIG. 8 is a cross-sectional view showing a portion of a semiconductor package according to an example embodiment of the disclosure.

FIG. 9 is a cross-sectional view showing a semiconductor package according to an example embodiment of the disclosure.

FIG. 10 is a projected top view schematically showing a semiconductor package according to an example embodiment of the disclosure.

FIG. 11 is a schematic cross-sectional view taken along line II-II′ in FIG. 10.

FIG. 12 is a cross-sectional view showing a stiffener set according to an example embodiment of the disclosure.

FIG. 13 is a projected top view schematically showing a semiconductor package according to an example embodiment of the disclosure.

### DETAILED DESCRIPTION

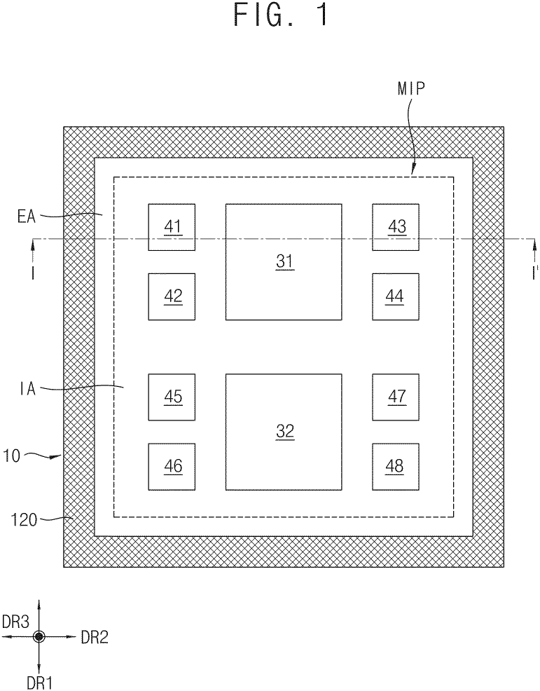

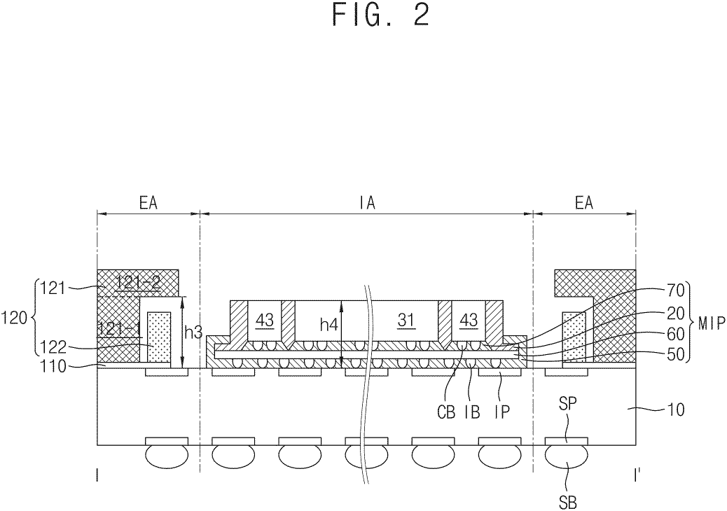

FIG. 1 is a projected top view schematically showing a semiconductor package according to an example embodiment of the disclosure. FIG. 2 is a schematic cross-sectional view taken along line I-I′ in FIG. 1.

Referring to FIGS. 1 and 2, a semiconductor package may include a substrate 10, one or more logic chips 31 and 32 and one or more memory stacks 41 to 48 disposed over the substrate 10, and a molding material 20 and a first underfill 50 surrounding the logic chips 31 and 32 and the memory stacks 41 to 48. An upward direction of the semiconductor package is designated by a third direction DR3. For convenience of description, in plan view, with reference to FIG. 1, a first direction DR1 is defined to designate an upward or downward direction, a second direction DR2 is defined to designate a left or right direction, and the third direction DR3 is defined to designate a normal direction (for example, a vertical direction or a thickness direction) of a plane defined by the first direction DR1 and the second direction DR2. Of course, example embodiments of the disclosure are not limited to the above-described definitions, and the first direction DR1, the second direction DR2 and the third direction DR3 may be understood as directions intersecting one another.

The semiconductor package may include, in plan view, an inner area IA, and an edge area EA surrounding the inner area IA (e.g., surrounding an outside of the inner area IA). The inner area IA is an area where a chip set MIP, which will be described later, is disposed. The edge area EA is an area where a stiffener set 120, which will be described later, is disposed. The inner area IA and the edge area EA may be defined on a upper surface of the substrate 10.

The substrate 10 may be a base member of the semiconductor package. The substrate 10 may be selected from a printed circuit board (PCB), a flexible printed circuit board (FPCB), a silicon-based substrate, a ceramic substrate, a glass substrate, or an insulating circuit board.

In an example embodiment, the semiconductor package may include a first logic chip 31 and a second logic chip 32. The first logic chip 31 and the second logic chip 32 may be disposed side-by-side in the first direction DR1 such that the first logic chip 31 and the second logic chip 32 are adjacent to each other on the substrate 10.

For example, each of the first logic chip 31 and the second logic chip 32 may include one of a core processor, an application specific integrated circuit (ASIC), a mobile application processor (AP), or other processing chips. The first logic chip 31 and the second logic chip 32 may be disposed horizontally at the same level.

In an example embodiment, the semiconductor package may include first to eighth memory stacks 41 to 48. The first to fourth memory stacks 41 to 44 may be disposed side-by-side with respect to the first logic chip 31 in the second direction DR2 intersecting the first direction DR1. The fifth to eighth memory stacks 45 to 48 may be disposed side-by-side with respect to the second logic chip 32 in the second direction DR2.

In accordance with some example embodiments, the first to fourth memory stacks 41 to 44 may be symmetrically disposed at opposite sides of the first logic chip 31 while being disposed side-by-side with respect to the first logic chip 31 in the second direction DR2.

For example, the first and second memory stacks 41 and 42 may be disposed adjacent to one side surface (e.g., a left surface) of the first logic chip 31. The third and fourth memory stacks 43 and 44 may be disposed adjacent to the other side surface (e.g., a right surface) of the first logic chip 31. The first and second memory stacks 41 and 42 may be aligned with each other to be disposed side-by-side in the first direction DR1. Similarly, the third and fourth memory stacks 43 and 44 may be aligned with each other to be disposed side-by-side in the first direction DR1.

For example, the fifth and sixth memory stacks 45 and 46 may be disposed adjacent to one side surface (e.g., a left surface) of the second logic chip 32. The seventh and eighth memory stacks 47 and 48 may be disposed adjacent to the other side surface (e.g., a right surface) of the second logic chip 32. The fifth and sixth memory stacks 45 and 46 may be aligned with each other to be disposed side-by-side in the first direction DR1. Similarly, the seventh and eighth memory stacks 47 and 48 may be aligned with each other to be disposed side-by-side in the first direction DR1.

The molding material 20 may surround side surfaces of the logic chips 31 and 32 and the memory stacks 41 to 48 on the upper surface of the substrate 10. The molding material 20 may fill spaces among the logic chips 31 and 32 and the memory stacks 41 to 48. Each upper surface of the logic chips 31 and 32 and the memory stacks 41 to 48 may be exposed without being covered by the molding material 20. In accordance with some example embodiments, the height of the upper surfaces of the logic chips 31 and 32 and the memory stacks 41 to 48 may be equal to the height of an uppermost surface of the molding material 20. The molding material 20 may include an epoxy molding compound (EMC). In an example embodiment, an edge of the molding material 20 may have a quadrangular shape in plan view. In an example embodiment, the logic chips 31 and 32 and the memory stacks 41 to 48 may be disposed inside a reference area of the molding material 20.

In an example embodiment, the first underfill 50 may surround at least a portion of the molding material 20 in plan view.

Referring to FIGS. 1 and 2, in an example embodiment, a semiconductor package may include a substrate 10, an interposer 60 disposed on the substrate 10, a molding material 20 and a second underfill 70 disposed on the interposer 60, and logic chips 31 and 32 and memory stacks 41 to 48 disposed on the second underfill 70. In addition, the semiconductor package may further include a first underfill 50 surrounding a region between the substrate 10 and the interposer 60, surrounding a side surface of the interposer 60, and surrounding a side surface of the molding material 20 up to a desired (or alternatively, predetermined) height. In addition, the semiconductor package may further include substrate bumps SB, interposer bumps IB, and chip bumps CB. The substrate bumps SB may be disposed under the substrate 10. The interposer bumps IB may be disposed under the interposer 60 while being disposed between the substrate 10 and the interposer 60. The chip bumps CB may be disposed under the logic chips 31 and 32 and the memory stacks 41 to 48, and each of the chip bumps CB may be positioned between a corresponding one of the logic chips 31 and 32 and the interposer 60 or between a corresponding one of the memory stacks 41 to 48 and the interposer 60.

In this case, the interposer 60, the molding material 20, the first underfill 50, the second underfill 70, the logic chips 31 and 32, and the memory stacks 41 to 48 may constitute a chip set MIP mounted in an inner area IA on the substrate 10.

The interposer 60 may be mounted on the substrate 10. The interposer 60 may be selected from a printed circuit board (PCB), a flexible printed circuit board (FPCB), a silicon-based substrate, a ceramic substrate, a glass substrate, or an insulating circuit board.

The logic chips 31 and 32 and the memory stacks 41 to 48 may be mounted on an upper surface of the interposer 60. The interposer 60 may be a substrate including a redistribution structure. The interposer 60 may electrically interconnect each of the logic chips 31 and 32 and the substrate 10, and may electrically interconnect each of the memory stacks 41 to 48 and the substrate 10.

The semiconductor package may include substrate bump pads SP disposed at a lower portion of the substrate 10, and interposer bump pads IP disposed at an upper portion of the substrate 10. The substrate bump pads SP and the interposer bump pads IP may be electrically interconnected via wirings vertically formed in the substrate 10 and wirings horizontally formed in the substrate 10. The substrate bump pads SP may contact the substrate bumps SB and, as such, may be electrically connected to an external circuit board. The interposer bump pads IP may contact the interposer bumps IB and, as such, may be electrically connected to the interposer 60.

In an example embodiment, the semiconductor package may include the first underfill 50 which is disposed between the substrate 10 and the interposer 60. In an example embodiment, the first underfill 50 may be formed throughout the entirety of a lower surface of the interposer 60, except for portions of the interposer 60 formed with the interposer bumps IB. The first underfill 50 may surround the interposer bumps IB. In addition, the first underfill 50 may surround an edge of the interposer 60 in plan view. Furthermore, the first under fill 50 may surround an edge of the molding material 20 in plan view while having a greater height than a lowermost surface of the molding material 20.

The first underfill 50 may provide bonding force between the substrate 10 and the interposer 60. In an example embodiment, the first underfill 50 may include a thermosetting resin.

The second underfill 70 may be formed between the interposer 60 and the logic chips 31 and 32 and between the interposer 60 and the memory stacks 41 to 48 and, as such, may surround the chip bumps CB. The second underfill 70 may provide bonding force between the interposer 60 and the logic chips 31 and 32 and between the interposer 60 and the memory stacks 41 to 48. In an example embodiment, the second underfill 70 may include a thermosetting resin.

In an example embodiment, the molding material 20 may be disposed on the interposer 60. In accordance with some example embodiments, the molding material 20 may prevent the upper surface of the interposer 60 from being exposed. For example, the molding material 20 may overlap the entire region of the interposer 60, in plan view. The molding material 20 may be directly disposed on the interposer 60 such that the molding material 20 surrounds side surfaces of the logic chips 31 and 32 and the memory stacks 41 to 48.

For example, the memory stacks 41 to 48 may include non-volatile memory chips such as dynamic random access memory (DRAM), resistive random access memory (RRAM), magneto-resistive random access memory (MRAM), phase-change random access memory (PRAM) and flash memory or various other memory chips.

In an example embodiment, the semiconductor package may further include a stiffener set 120 disposed in an edge area EA on the substrate 10.

In an example embodiment, the stiffener set 120 may include a first stiffener 121 and a second stiffener 122.

For example, the first stiffener 121 may surround the second stiffener 122 (e.g., an outside of the second stiffener). The first stiffener 121 may cover at least a portion of an upper surface of the second stiffener 122. In accordance with some example embodiments, upon viewing the stiffener set 120 from a top side of the semiconductor package, the second stiffener 122 may be hidden by the first stiffener 121 and, as such, may not be viewed. In accordance with this structure, an enhancement in aesthetics may be provided.

The first stiffener 121 and the second stiffener 122 may be spaced apart from each other. That is, the first stiffener 121 and the second stiffener 122 may not contact each other. That is, there may be a space between the first stiffener 121 and the second stiffener 122.

The semiconductor package may further include an adhesive member 110 attaching the substrate 10 and the stiffener set 120 to each other. In an example embodiment, the adhesive member 110 may be a single member and, as such, may attach both the first stiffener 121 and the second stiffener 122 to the substrate 10. For example, the adhesive member 110 may contact all of the substrate 10, the first stiffener 121 and the second stiffener 122.

In an example embodiment, an outer side surface of the first stiffener 121 may be aligned with an outer side surface of the substrate 10 in a third direction DR3 (for example, a vertical direction).

In an example embodiment, the substrate 10, the first stiffener 121, the second stiffener 122, and the chip set MIP may have different coefficients of thermal expansion (CTEs), respectively. For example, the CTE of the substrate 10 may be greater than the CTE of the chip set MIP, and each CTE of the first stiffener 121 and the second stiffener 122 may be greater than the CTE of the substrate 10. In this case, the CTEs of the first stiffener 121 and the second stiffener 122 may be different from each other. The first stiffener 121, the second stiffener 122 and the chip set MIP are set to have different CETs, respectively, and, as such, a balance between external physical force in the edge area EA of the semiconductor package and external physical force in the inner area IA of the semiconductor package may be provided. Accordingly, it may be possible to mitigate or minimize a problem such as warpage or the like in the edge area EA of the semiconductor package.

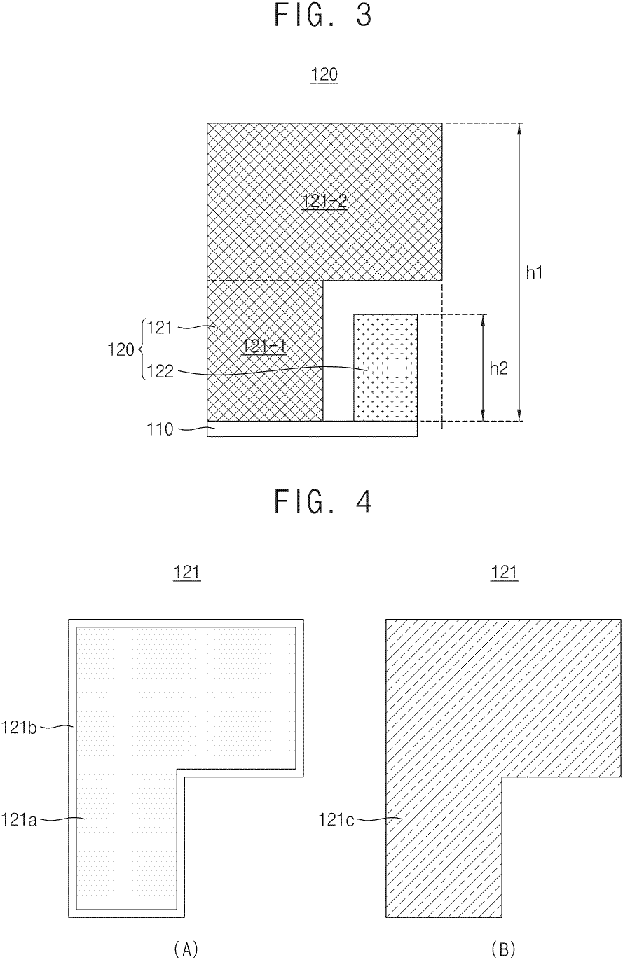

FIG. 3 is a cross-sectional view showing a stiffener set 120 according to an example embodiment of the disclosure. FIGS. 4A and 4B show detailed cross-sectional structures of a first stiffener according to some example embodiments of the disclosure.

Referring to FIGS. 2 to 4, in an example embodiment, a height h1 of a first stiffener 121 may be greater than a second height h2 of a second stiffener 122.

The first stiffener 121 may include a pillar region 121-1, and a roof region 121-2 supporting the pillar region 121-1. The roof region 121-2 may include a portion protruding laterally toward an inside of the semiconductor package. The width of the roof region 121-2 may be greater than the width of the pillar region 121-1. In an example embodiment, the roof region 121-2 (e.g., the protruding portion) may overlap the entire region of the second stiffener 122 in plan view. In an example embodiment, the roof region 121-2 (e.g., the protruding portion) may be disposed at a higher position than the chip set MIP. For example, a third height of a lowermost side (e.g., the bottom surface) of the roof region 121-2 (e.g., the protruding portion) may be greater than a fourth height of an uppermost side (e.g., the top surface) of the chip set MIP. Accordingly, it may be possible to mitigate or minimize a possibility that the first stiffener 121 and the chip set MIP contact each other. That is, the stiffener set 120 does not contact the chip set MIP. The pillar region 121-1 may contact the adhesive member 110 at a lower side thereof. The pillar region 121-1 may be disposed outside the second stiffener 122.

In an example embodiment, each of the first stiffener 121 and the second stiffener 122 may include a metal material.

For example, as shown in (A) of FIG. 4, each of the first stiffener 121 and the second stiffener 122 may have a form including a core metal 121a, and a plated region 121b outside the core metal 121a (e.g., a plated region 121b enclosing the core metal 121a). For example, the core metal 121a may include a metal such as Cu or the like, and the plated region 121b may include Ni.

In another example, as shown in (B) of FIG. 4, each of the first stiffener 121 and the second stiffener 122 may be constituted by a single metal 121c. For example, each of the first stiffener 121 and the second stiffener 122 may include stainless steel (e.g., SUS403) without being separately plated at a surface thereof.

Next, a semiconductor package according to another example embodiment of the disclosure will be described. In the following description, no description will be given of the same constituent elements as those of FIGS. 1 to 4, and reference numerals identical or similar to those of FIGS. 1 to 4 designate the same constituent elements.

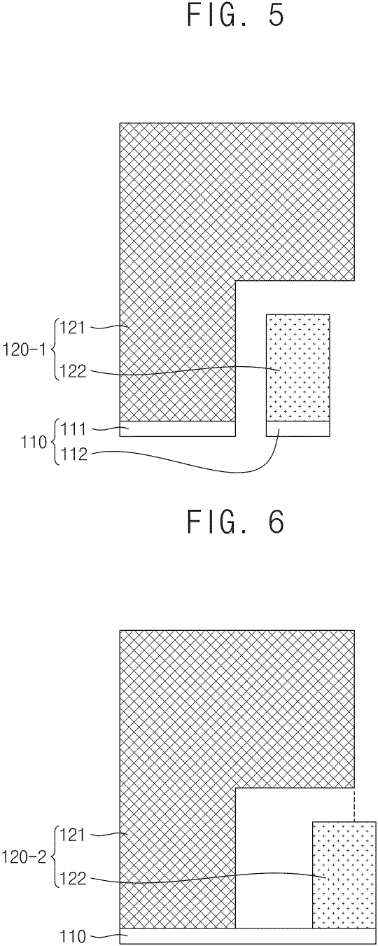

FIG. 5 is a cross-sectional view showing a portion of a semiconductor package according to an example embodiment of the disclosure.

Referring to FIG. 5, a stiffener set 120-1 according to this example embodiment is different from that of the example embodiment of FIG. 3 in that separate adhesive members 110 are attached to stiffeners, respectively. In an example embodiment, the semiconductor package may include a first adhesive for attaching a first stiffener 121 to a substrate, and a second adhesive for attaching a second stiffener 122 to the substrate. The first adhesive and the second adhesive may be spaced apart from each other. The first adhesive may be disposed outside the second adhesive.

FIG. 6 is a cross-sectional view showing a portion of a semiconductor package according to an example embodiment of the disclosure.

Referring to FIG. 6, a stiffener set 120-2 according to this example embodiment is different from that of the example embodiment of FIG. 3 in that a second stiffener 122 includes a portion not overlapping a first stiffener 121 in plan view. For example, upon viewing the semiconductor package at the top side, a portion of an upper surface of the second stiffener 122 may be viewed.

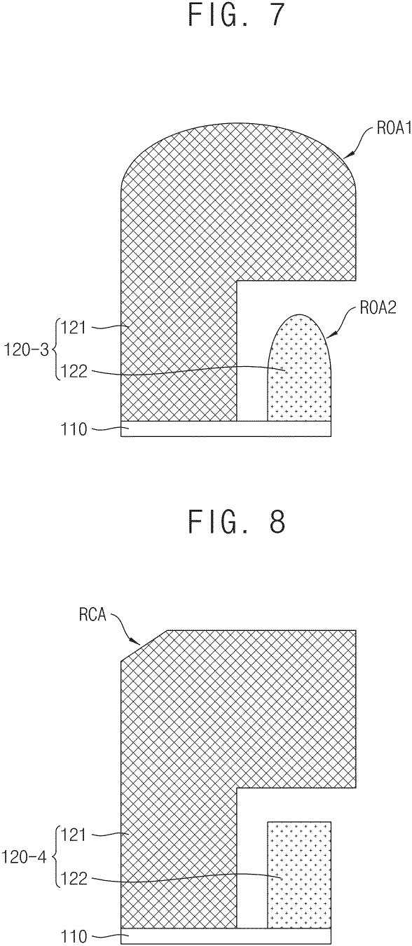

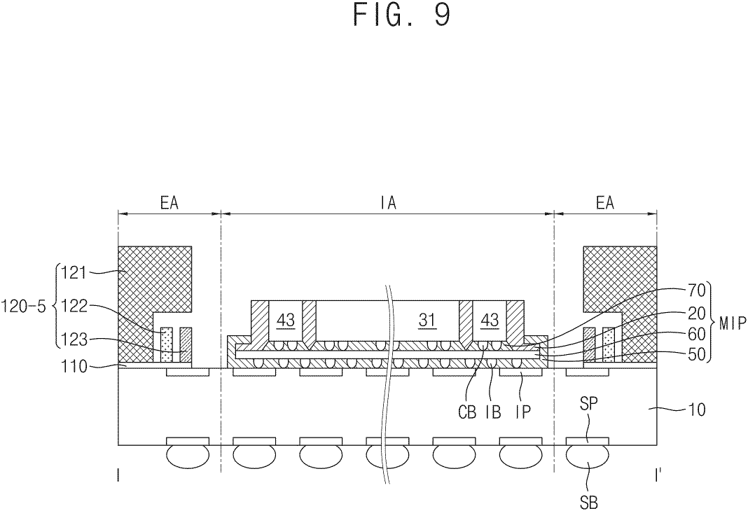

FIG. 7 is a cross-sectional view showing a portion of a semiconductor package according to an example embodiment of the disclosure.

Referring to FIG. 7, a stiffener set 120-3 according to this example embodiment is different from that of the example embodiment of FIG. 3 in that at least one of a first stiffener 121 and a second stiffener 122 includes a curved surface at an upper surface thereof. For example, an upper surface of the first stiffener 121 may include a first curved surface ROA1, and an upper surface of the second stiffener 122 may include a second curved surface ROA2.

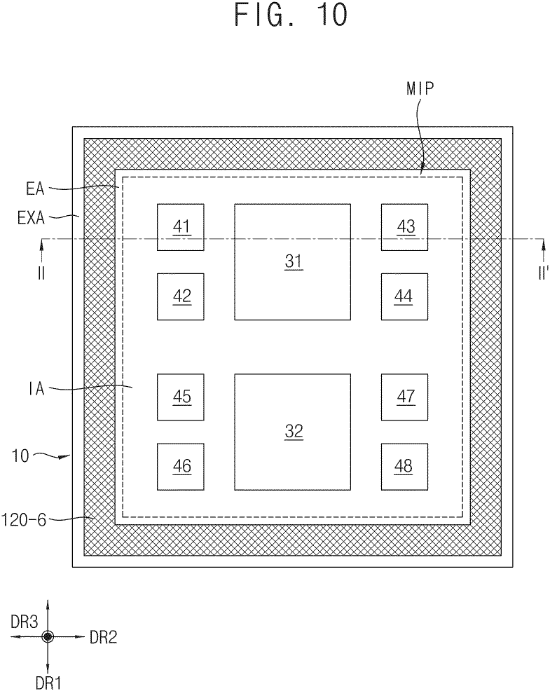

FIG. 8 is a cross-sectional view showing a portion of a semiconductor package according to an example embodiment of the disclosure.

Referring to FIG. 8, a stiffener set 120-4 according to this example embodiment is different from that of the example embodiment of FIG. 3 in that at least one of a first stiffener 121 and a second stiffener 122 includes an inclined surface. For example, the first stiffener 121 may include an inclined surface RCA at one corner thereof.

FIG. 9 is a cross-sectional view showing a semiconductor package according to an example embodiment of the disclosure.

Referring to FIG. 9, a stiffener set 120-5 according to this example embodiment is different from that of the example embodiment of FIG. 2 in that the stiffener set 120-5 includes three or more stiffeners. For example, the stiffener set 120-5 may further include a third stiffener 123 disposed inside a second stiffener 122. In an example embodiment, all of a first stiffener 121, the second stiffener 122 and the third stiffener 123 may be attached to a substrate by an adhesive member 110. In an example embodiment, the entire region of the third stiffener 123 may overlap the first stiffener 121 in a plan view.

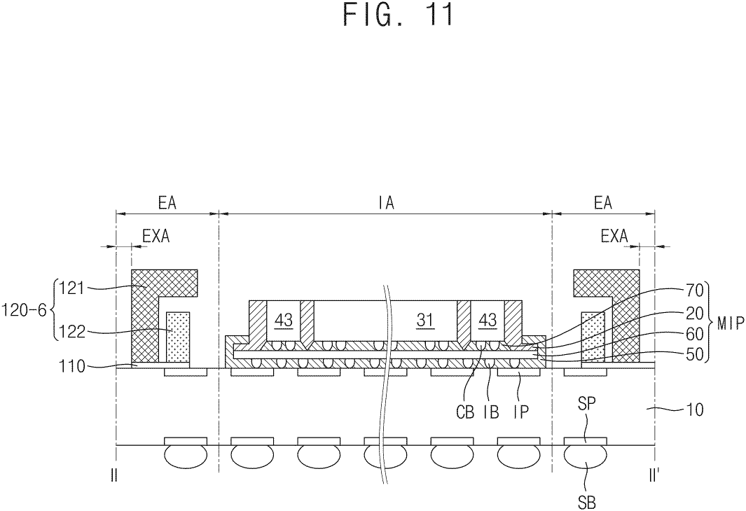

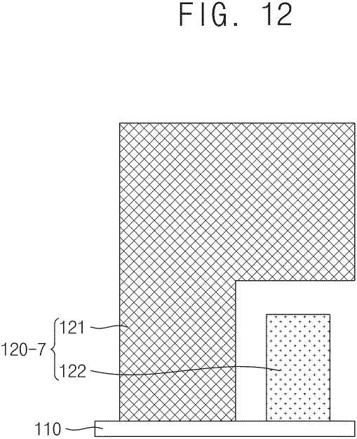

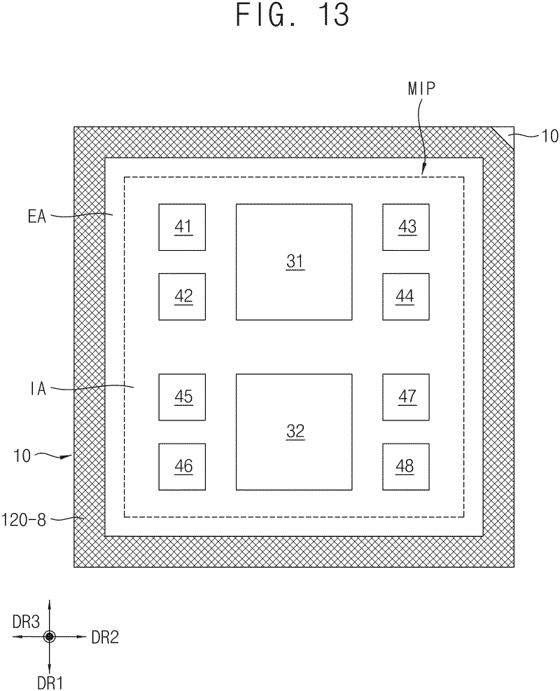

FIG. 10 is a projected top view schematically showing a semiconductor package according to an example embodiment of the disclosure. FIG. 11 is a schematic cross-sectional view taken along line II-II′ in FIG. 10. FIG. 12 is a cross-sectional view showing a stiffener set according to an example embodiment of the disclosure.

Referring to FIGS. 10 and 11, the semiconductor package according to this example embodiment is different from that of the example embodiment of FIGS. 1 and 2 in that the semiconductor package includes an exposure area EXA in which an upper surface of a substrate is exposed at an outside of a stiffener set 120-6.

In an example embodiment, an outer side surface of a first stiffener 121 may be misaligned from an outer side surface of a substrate 10 in a third direction DR3 (for example, a vertical direction). In other words, the outer side surface of a first stiffener 121 and an outer side surface of a substrate 10 may be on different planes in the third direction DR3. The exposure area EXA, which is exposed at the outside of the stiffener set 120-6, may be defined on an upper surface of the substrate 10. That is, the exposure area EXA may surround an edge area EA in which the stiffener set 120-6 is disposed, in plan view.

Referring to FIG. 12, in some example embodiments, an adhesive member 110 may extend to an outside of a stiffener set 120-7. For example, the adhesive member 110 may be exposed at a portion thereof without being completely hidden by the stiffener set 120-7.

FIG. 13 is a projected top view schematically showing a semiconductor package according to an example embodiment of the disclosure.

Referring to FIG. 13, the semiconductor package according to this example embodiment is different from that of the example embodiment of FIG. 1 in that a portion of a substrate 10 is exposed at at least one outer corner of an edge area EA. For example, a portion of a corner of a stiffener set 120-8 may be removed and, as such, a portion of the substrate 10 may be upwardly exposed.

In accordance with some example embodiments of the disclosure, it may be possible to mitigate or minimize a possibility that a semiconductor package is damaged by external physical stress.

Effects according to some example embodiments of the disclosure are not limited to the above-illustrated contents, and wider variety of effects may be included in the specification.

While some example embodiments of the disclosure have been described with reference to the accompanying drawings, it should be understood by those skilled in the art that various modifications may be made without departing from the scope of the disclosure and without changing essential features thereof. Therefore, the above-described example embodiments should be considered in a descriptive sense only and not for purposes of limitation.

What is claimed is:

1. A semiconductor package comprising:
a substrate comprising, at an upper surface thereof, an inner area, and an edge area surrounding the inner area;
a chip set on the inner area of the substrate;
a stiffener set on the edge area of the substrate, the stiffener set comprising a plurality of stiffeners spaced apart from one another; and
an adhesive member attaching the plurality of stiffeners to the substrate.

2. The semiconductor package according to claim 1, wherein:
the stiffener set comprises a first stiffener and a second stiffener; and
the first stiffener surrounds the second stiffener.

3. The semiconductor package according to claim 2, wherein a coefficient of thermal expansion (CTE) of the first stiffener, a CTE of the second stiffener, and a CTE of the chip set, and a CTE of the substrate are different.

4. The semiconductor package according to claim 3, wherein each of the CTE of the first stiffener and the CTE of the second stiffener is greater than both the CTE of the chip set and the CTE of the substrate.

5. The semiconductor package according to claim 4, wherein the CTE of the substrate is greater than the CTE of the chip set.

6. The semiconductor package according to claim 2, wherein a height of the first stiffener is greater than a height of the second stiffener.

7. The semiconductor package according to claim 2, wherein the first stiffener comprises a roof region and a pillar region supporting the roof region, the roof region overlapping the second stiffener in plan view, and the pillar region contacting the adhesive member.

8. The semiconductor package according to claim 7, wherein a height of a lowermost side of the roof region is greater than a height of an uppermost side of the chip set.

9. The semiconductor package according to claim 1, wherein the adhesive member is a single member, and contacts all of the plurality of stiffeners.

10. The semiconductor package according to claim 1, wherein each of the stiffeners comprises a core metal and a plated region at an outside of the core metal.

11. The semiconductor package according to claim 10, wherein:
the core metal comprises Cu; and
the plated region comprises Ni.

12. The semiconductor package according to claim 1, wherein an outer side surface of the stiffener set is vertically aligned with an outer side surface of the substrate.

13. The semiconductor package according to claim 1, wherein the stiffener set does not contact the chip set.

14. A semiconductor package comprising:
a substrate comprising, at an upper surface thereof, an inner area and an edge area surrounding the inner area;
a chip set on the inner area of the substrate;
a stiffener set on the edge area of the substrate, the stiffener set comprising a plurality of stiffeners having different coefficients of thermal expansion (CTEs), respectively; and
an adhesive member attaching the plurality of stiffeners to the substrate.

15. The semiconductor package according to claim 14, wherein a coefficient of thermal expansion (CTE) of each of the stiffeners, a CTE of the chip set, and a CTE of the substrate are different.

16. The semiconductor package according to claim 15, wherein:
the CTE of each of the stiffeners is greater than both the CTE of the chip set and the CTE of the substrate; and
the CTE of the substrate is greater than the CTE of the chip set.

17. The semiconductor package according to claim 14, wherein the stiffeners have different heights, respectively.

18. The semiconductor package according to claim 14, wherein each of the stiffeners comprises stainless steel.

19. The semiconductor package according to claim 14, wherein the stiffeners and the chip set are spaced apart from one another.

20. A semiconductor package comprising:
a substrate comprising, at an upper surface thereof, an inner area and an edge area surrounding the inner area;
a chip set on the inner area of the substrate, the chip set comprising an interposer on the substrate and a logic chip and a memory stack on the interposer;
a stiffener set on the edge area of the substrate, the stiffener set comprising a plurality of stiffeners spaced apart from one another and having different coefficients of thermal expansion (CTEs), respectively; and
an adhesive member attaching the plurality of stiffeners to the substrate,
wherein a coefficient of thermal expansion (CTE) of each of the stiffeners, a CTE of the chip set, and a CTE of the substrate is different.
